(19) United States
(12) Patent Application Publication
(10) Pub. No.: US 2022/0231094 A1
(43) Pub. Date: Jul. 21, 2022

(54) Transparent OLED Device

(71) Applicant: Universal Display Corporation, Ewing, NJ (US)

(72) Inventors: Michael HACK, Carmel, CA (US); Michael Stuart WEAVER, Princeton, NJ (US)

(21) Appl. No.: 17/579,084

(22) Filed: Jan. 19, 2022

Related U.S. Application Data
(60) Provisional application No. 63/138,827, filed on Jan. 19, 2021.

(51) Int. Cl. H01L 27/32; H01L 51/52

(52) U.S. Cl. CPC H01L 27/3209; H01L 2251/5323; H01L 27/326; H01L 51/52

(57) ABSTRACT

Display panels and other devices are provided that include emissive devices disposed on two carrier substrates and arranged to achieve a desired emission profile and transparency. Each carrier substrate includes OLED devices of a selected color which may be used to provide one- or two-sided imaging based on emission from devices on each carrier substrate.

### CROSS-REFERENCE TO RELATED APPLICATIONS

This application claims the priority benefit of U.S. Patent Application Ser. No. 63/138,827, filed Jan. 19, 2021, the entire contents of which are incorporated herein by reference.

### FIELD

The present invention relates to devices and techniques for fabricating partially or fully transparent organic emissive devices, such as organic light emitting diodes, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-S00 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-S00 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

Embodiments disclosed herein provide a transparent display device that includes: a first organic light emitting diode (OLED) device, including a first carrier substrate and a first organic emissive stack disposed over the first carrier substrate, the first organic emissive stack comprising a first emissive material of a first color; a second OLED device disposed in a stack with the first OLED device; the second OLED device including a second carrier substrate different from the first substrate; and a second organic emissive stack different from the first organic emissive stack and disposed over the second carrier substrate, the second organic emissive stack comprising a second emissive material of a second color different than the first color.

Embodiments disclosed herein provide a transparent display panel including two sub-panels, each of which includes a backplane layer and an emissive layer comprising a plurality of OLED-based pixels disposed over the backplane layer, where the backplane layer provides control of the associated emissive layer.

Embodiments disclosed herein also provide a consumer electronic product including a transparent display panel including two sub-panels, each of which includes a backplane layer and an emissive layer comprising a plurality of OLED-based pixels disposed over the backplane layer, where the backplane layer provides control of the associated emissive layer. The consumer electronic product may include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a sign, or combinations thereof.

### BRIEF DESCRIPTION OF THE DRAWINGS

FIG. 1 shows an organic light emitting device.

FIG. 2 shows an inverted organic light emitting device that does not have a separate electron transport layer.

FIGS. 3A, 3B, and 3C each show example device arrangements according to embodiments disclosed herein, which include two carrier substrates and one or more OLED devices disposed thereon.

FIG. 4 shows an exploded schematic view of a transparent display having two sub-panels as disclosed herein.

FIG. 5 shows shows an exploded schematic view of a transparent display having two sub-panels as disclosed herein.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5 -6, which are incorporated by reference.

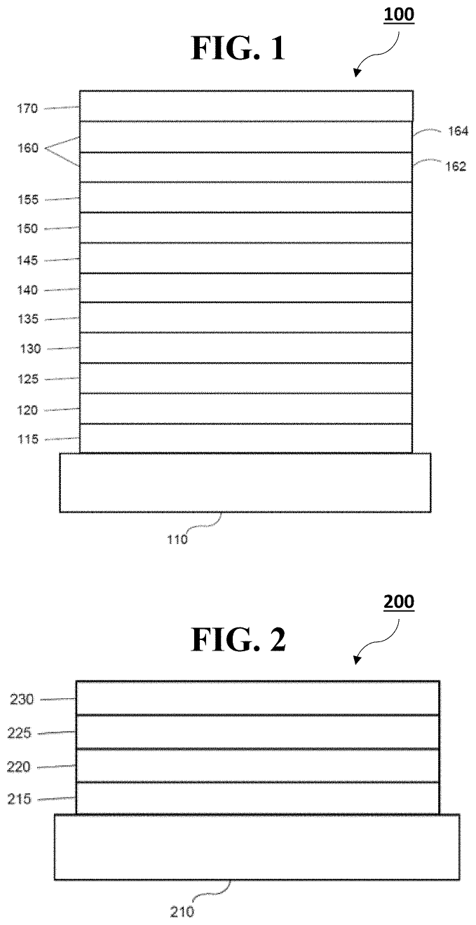

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6 -10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

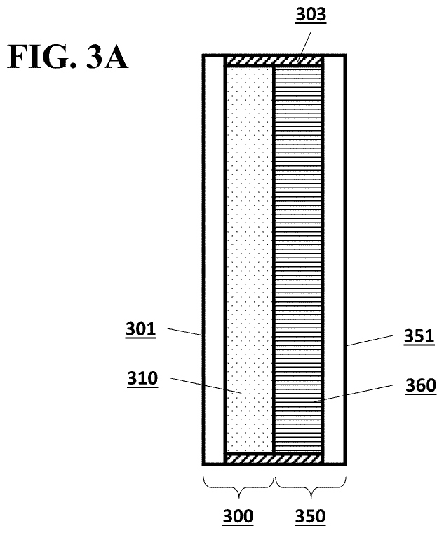

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light, which may be altered by another layer such as a color filter or other color altering layer that does not itself emit an initial light within the device, but may re-emit altered light of a different spectra content based upon initial light emitted by the emissive layer.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for interventing layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small ΔES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

### Combination with other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Transparent OLED-based devices, such as large panel displays, are gaining increasing traction in the marketplace. Achieving high brightness (with long operational lifetime) is a challenge for any OLED display, but especially for a transparent display where active area is often reduced to allow for transparent inactive regions. Signage applications, in particular, may require both high transparency and high brightness. Embodiments disclosed herein provide a new architecture that enables transparent displays to have higher brightness while supporting both one-sided or two-sided emission for signage. This is accomplished by using two carrier substrates, each of which may provide AMOLED emission of different portions of the visible spectrum and each of which functions as a conventional substrate for devices disposed thereon, i.e., the substrates shown and described with respect to FIGS. 1 and 2. For example, one carrier substrate may be used to produce the yellow (or patterned red and green) images using OLED devices disposed on it, and the second carrier substrate in a common device may be used to produce the blue portion of the same images. Placed together in a single stacked device, the two provide a full-color transparent display. The use of two carrier substrates also reduces or eliminates patterning requirements for large area substrates. As used herein, the term “carrier substrate” is used to refer to the substrate for one portion of the panel on which a particular set of devices is disposed. Embodiments disclosed herein generally include two carrier substrates, each of which functions as a substrate for the associated device(s) disposed thereon as disclosed with respect to FIGS. 1-2.

Competing requirements of transparency and long operational lifetimes often require multiple emissive layers to achieve high brightness with long lifetimes, especially with pixels designed with reduced fill-factor. While stacked structures provide a good path to achieving these goals the use of emission from two carrier substrates provides additional benefits as each carrier substrate can have improved fill-factor as a result of reduced alignment tolerances for the OLED emission because the carrier substrates do not require patterning of three different colors, and in fact, may not need any OLED patterning at the pixel level.

Some prior or conventional OLED-based devices use multiple emitting planes. For example, U.S. Pat. No. 8,827,488 discloses a B1B2RG (blue/blue/red/green) device that uses two separate emitting planes and U.S. Pat. No. 9,231,227 discloses a device having two emitting planes arranged on a single substrate. In contrast, embodiments disclosed herein provide RGB-type devices that include devices disposed on two different carrier substrates arranged in a stack which provide emission that combines to form a desired image as previously disclosed.

Such an arrangement may provide higher performance generally, considering lifetime, brightness and/or transparency. Prior to the embodiments disclosed herein, such arrangements were not considered, or were not considered suitable for use in OLED-based devices due to the increased complexity, fabrication time and effort, and resulting device cost. It has been found that the advances disclosed herein, in combination with improvements in fabrication techniques and panel cost reduction, allow for such an architecture to viable. The simplification or elimination of large area organic patterning also may mitigate the additional cost resulting from the use of two separate carrier substrates while providing improved performance.

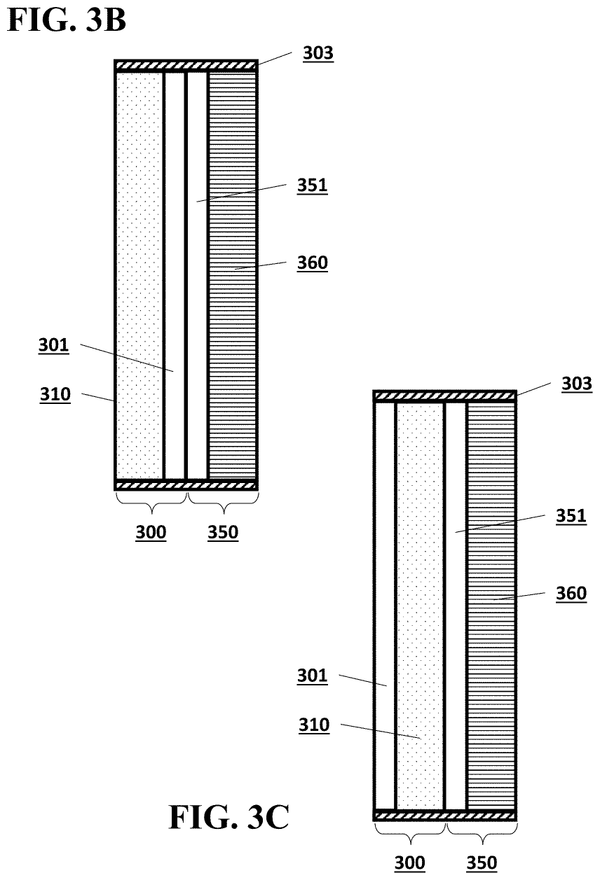

FIG. 3A shows an example device according to embodiments disclosed herein. The device includes two OLED devices, such as AMOLED devices, each of which includes a backplane layer to provide access to and control of the associated emissive OLED device. Unless specifically indicated to the contrary or made clear from other context as disclosed herein, each of the devices 300, 350 may be a device as previously disclosed with respect to FIGS. 1 and/or 2. The two devices 300, 350 may face one another between their associated carrier substrates and are sealed to form a single package. In this example, two devices 300, 350 are arranged with active surfaces facing one another. Environmental seals 303 may be used to seal the two devices into a single package. Each device 300, 350 includes an associated carrier substrate 301, 351, and active device stacks 310, 360, which may include backplane electronics, emissive layers, and associated device layers such as those previously disclosed with respect to FIGS. 1 and 2. The emissive stacks 310, 360 may be arranged and configured to produce different colors when used. For example, the emissive stacks 310, 360 may be blue and yellow stacks, respectively. As another example, the yellow stack 360 may be a green or red stack and various combinations of red and green devices may be used in a display panel as disclosed herein. As another example, the emissive stack 360 may include both green and red emissive stacks, or a single stack may include both green and red emissive materials, so as to produce a range of color when used in conjunction with one another. Regardless of the specific arrangement of individual emissive stacks and/or materials, the two stacks 310, 360 may be used together to produce a full-color display as disclosed herein. Hence, the transparent display device shown in FIGS. 3A-3C and other embodiments shown and described herein includes a first OLED device 300 that includes a first carrier substrate 301 and an OLED including an organic emissive stack 310 (such as described with respect to FIGS. 1-2), and a second OLED device disposed in a stack with the first OLED device, which includes a corresponding second carrier substrate 351 and a second OLED including a second organic emissive stack 360. Generally the second organic emissive stack will include a second emissive material of a second color different than a first color included in the first organic emissive stack.

As described in further detail herein, each of the devices 300, 350 may be top-emitting, bottom-emitting, or both top- and bottom-emitting, and may be transparent. As used herein, a device, layer, or other component is “transparent” if at least 20%, more preferably 30%, more preferably 40%, more preferably 50% or more of any incident light is transmitted through the device, layer, or other component. Embodiments disclosed herein allow for display panels that are at least 20%, 30%, 40%, or 50% transparent. One way of achieving high transparency is to reduce the fill-factor of the active emissive regions (ratio of emissive region area to overall subpixel area) and provide transparent regions in the spaces between emissive regions. Further, in some embodiments, individual combined arrangements 300/350 may be less transparent or even not significantly transparent individually, but may be arranged within a display panel such that the display has a lower resolution but a relatively high transparency. For example, stacked combination devices 300/350 may be spread out within the display panel with no emissive devices between them, such that the resolution is lower than would be achieved if the combined devices 300/350 were packed more closely in the display panel, but the overall transparency of the panel is higher than would be achievable with more closely-packed emissive device stacks. Embodiments disclosed herein also allow for relatively high brightness operation, such as for outdoor signage applications. For example, display arrangements disclosed herein may achieve an operational luminance of 1000, 1200, 1500 nits or higher.

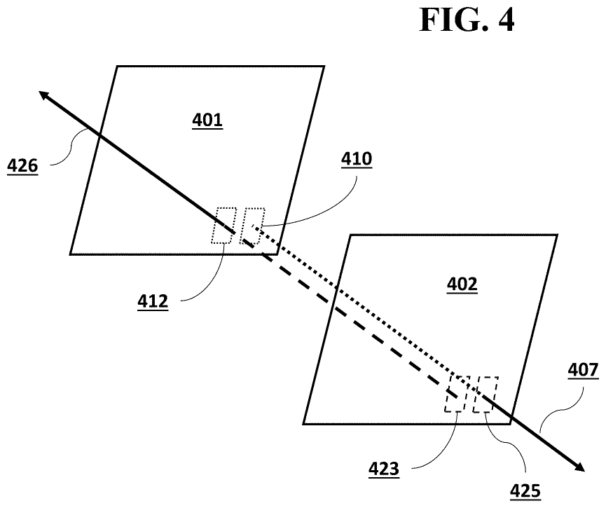

FIG. 4 shows an exploded schematic view of a transparent display having two sub-panels as disclosed herein, which allows for two-sided emission of the same or different images. In this example, both images are generated by top-emitting OLEDs on one carrier substrate which emit through transparent OLEDs on the other. Specifically, the display panel includes two sub-panels 401, 402, each of which may include multiple OLED devices such as shown in FIGS. 1-3 and specifically having the combined arrangements shown in FIGS. 3A-3C. Sub-panels 401, 402 may represent, for example, common carrier substrates on which multiple OLED devices are arranged, such as carrier substrates 301, 351 in FIG. 3. Each sub-panel may include some or all of the associated electronics to drive individual OLED devices, such as a backplane layer, as well as an emissive layer that includes multiple OLED devices as shown and described in FIGS. 1-3. Each backplane layer provides an interface and/or electronic control of the emissive layer and devices disposed thereon.

Sub-pixel devices 410, 412, 423, 425 may be formed from emissive stacks 310, 360 in FIG. 3. Corresponding devices may be aligned and overlap with one another. For example, display component 401 may include many sub-pixel devices 410, 412, each of which may have a device structure as shown in FIGS. 1-2. In conjunction with corresponding OLED devices on the second component 402, the structure shown in FIG. 3 may be obtained. For example, corresponding devices 412, 423 may include emissive stacks between carrier substrates as shown in FIG. 3, and similarly for devices 410, 425. In operation, a top-emitting OLED device 410 may emit light toward and through the corresponding OLED device 425, thereby achieving a combined illumination 407. In the example shown in FIG. 4, dotted or dashed emission line segments indicate emission from a single OLED device before being combined with emission from the corresponding device on the second device component, and solid emission lines indicate the combined emission resulting from a combination of emission from the OLED pairs, e.g., 410/425 or 423/412. Similarly, a top-emitting device 423 may emit light toward and through the corresponding transparent device 412, resulting in combined emission 426.

Notably, an arrangement as shown in FIG. 4 may allow for two-sided emission and, furthermore, may allow for different images to be displayed on either side of a display panel that includes the two sub-panels 401, 402. Corresponding OLED devices may have complementary emission profiles to allow for full-spectrum emission. For example, device 410 may be a blue-emitting device, while device 425 may be a yellow-emitting device or a combination of red- and green-emitting devices, thereby allowing for emission 407 to represent a full-color pixel. Similarly, device 425 may be blue or yellow and corresponding device 410 may be yellow or blue, respectively.

In some embodiments, each sub-panel 401, 402 may include OLED devices of a variety of emission profiles. Continuing the example above, sub-panel 401 may include both blue and yellow devices, each of which may be top-emitting, bottom-emitting, or transparent, to allow for full-color emission when used in conjunction with corresponding devices on the second panel 402.

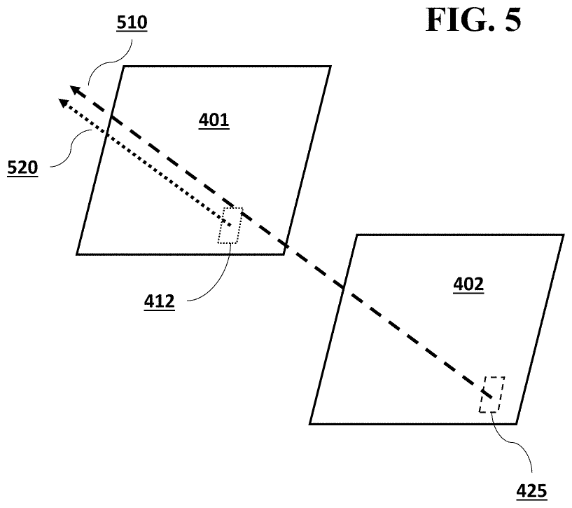

In some embodiments, corresponding sub-pixels may not overlap, i.e., they may be arranged partially or entirely adjacent to one another in the combined device. When corresponding devices fully overlap, any line drawn perpendicular to the carrier substrates that passes through one device will also pass through the other. For corresponding devices that do not overlap, a line drawn parallel to the carrier substrates that passes through one device will not pass through the corresponding device (though it may pass through others that are not always used in conjunction with the first). FIG. 5 shows an exploded view similar to that of FIG. 4, but where corresponding devices on the two carrier substrates 401, 402 do not overlap. In this case, the devices 412, 425 may be arranged on carrier substrates 401, 402 so that the do not overlap but so that both devices emit in the same direction. For example, the devices on carrier substrates 401, 402 may be arranged such that the active surfaces both face in the same direction. In this example, a viewer may see emission from both devices 510, 520, though the two devices 412, 425 may be small and close enough that the emission from the two appears as a single color, as is known for conventional sub-pixels. Emission from the lower device 425 may pass through an otherwise transparent region of the upper carrier substrate 401. The transparency and resolution of the combined panel may be adjusted based upon the proportion of the total panel that has one-sided, non-transparent OLED devices, compared to the proportion that has transparent devices or no devices present. Generally a higher resolution requires more emissive devices and therefore results in a lower transparency, while a lower resolution in the same panel active area results in a higher transparency due to the lower density of emissive devices.

It will be understood from these examples that various combinations of relative OLED device positioning on two carrier substrates 401, 402 (i.e., overlapping or non-overlapping), device transparency, and device emission type (top-emitting, bottom-emitting, or both) allow for various combinations of one- and two-sided displays. For non-overlapping arrangements, a spacer material as is used with OLEDs in other arrangements may be used to achieve a more uniform panel thickness; however, the OLED stack thickness is relatively small in comparison to the substrate and encapsulation, so such spacer material may be omitted. Furthermore, one- or two-sided, full-color displays may be achieved using only two sets of OLED devices arranged on the two carrier substrates, such as where blue and yellow or blue and red/green combination devices are used. In some embodiments, one of the carrier substrates such as carrier substrates 401, 402 may include devices of one color (e.g., blue or yellow) and the other carrier substrate may include devices of the complementary color required for full-color imaging (e.g., yellow or blue, respectively). FIGS. 4 and 5 show example arrangements of the carrier substrates and devices contained thereon without regard to active vs. inactive back (carrier substrate) surface. Other arrangements of the carrier substrate and active sides of the devices such as device 412, 425 shown in FIGS. 4 and 5 are shown in FIGS. 3B-3C. In FIG. 3B, the inactive back (carrier substrate) sides of the two sub-panels are placed together. In FIG. 3C, the devices are stacked so that the active side of one sub-panel is placed against the active side of another.

For example, using one-sided emitting devices with either the active surfaces placed together as shown in FIG. 3A, or with the non-active back carrier substrate-side faces placed together, with one surface providing blue mission and the other yellow, the following combinations may be used:

Top-emitting blue, bottom-emitting yellow, non-overlapping devices;
Top-emitting blue, transparent yellow, overlapping devices;
Top-emitting yellow, bottom-emitting blue, non-overlapping devices; and
Top-emitting yellow, transparent blue, overlapping devices.

In other embodiments, the active surface of one sub-panel may be placed next to the back carrier substrate side of the other, as shown in FIG. 3C. In this arrangement, using blue and yellow OLEDs as previously disclosed, the following arrangements may be used:

Bottom-emitting blue, bottom-emitting yellow, non-overlapping devices;
Bottom-emitting blue, transparent yellow, overlapping devices;
Bottom-emitting yellow, bottom-emitting blue, non-overlapping devices; and
Bottom-emitting yellow, transparent blue, overlapping devices.

Other arrangements may be used when the sub-panels are arranged with the active surfaces together as in FIG. 3A, or with the non-active back (carrier substrate) sides of the sub-panels together as in FIG. 3B, again where one surface emits yellow light and the other emits blue. In such embodiments, the following arrangements may be used where it is desired for the full panel to display the same image on either side:

Top-emitting blue, bottom-emitting yellow, non-overlapping devices;
Top-emitting yellow, bottom-emitting blue, non-overlapping devices;
Top-emitting blue, transparent yellow, overlapping devices;
Top-emitting yellow, transparent blue, overlapping devices.

Where one active surface is placed adjacent to the back, non-active (carrier substrate) side of the other as shown in FIG. 3C, the following arrangements may be used as previously disclosed:

Bottom-emitting blue, bottom-emitting yellow, non-overlapping devices;
Bottom-emitting yellow, bottom-emitting blue, non-overlapping devices;
Bottom-emitting blue, transparent yellow, overlapping devices;
Bottom-emitting yellow, transparent blue, overlapping devices.

Transparency and signage—more important to have higher transparency than ultra-high resolution. Supports idea of using two aligned carrier substrates. So for example for a 55″ signage display, standard high definition images may have sufficient resolution that ultra-high definition, or 4K format or higher resolution is not required.

More generally, each carrier substrate may include top-emitting OLEDs, bottom-emitting OLEDs, and/or transparent OLEDs. In some embodiments, it may be preferred for one carrier substrate to have all top-emitting OLEDs and the other to have all transparent OLEDs, arranged to overlap with the corresponding top-emitting OLEDs on the first carrier substrate as previously disclosed. Such an arrangement may maximize the fill-factor of the display panel and therefore the lifetime and transparency of the overall display. In any embodiment, it may be preferred to place the active surfaces of each device together to minimize parallax effects.

Embodiments disclosed herein may reduce or eliminate the need for large-area organic patterning, by reducing the number and resolution of devices to be fabricated on each carrier substrate. Embodiments disclosed herein may have an increased compared to a large-panel display that only uses one carrier substrate, but there are several factors which will reduce the cost and fabrication complexity of each sub-panel carrier substrate disclosed herein when compared to a conventional OLED display based on one carrier substrate. First, each sub-display may have a lower resolution and therefore simpler fabrication requirements and likely higher yield in production. For example, each sub-panel may have fewer individual sub-pixel-level OLED devices on each in comparison to a conventional single-carrier substrate panel. Second, each carrier substrate may not require high-resolution patterning within each pixel. For example, if one sub-panel carrier substrate includes only yellow OLEDs and the other includes only blue OLEDs, then each sub-panel can use blanket depositions with no patterning required at the pixel resolution. Red and green sub-pixels may be formed from the yellow devices using color filters, microcavities or other color conversion technologies. Each complete display panel thus may have an RGB, RGBY or RGBW architecture, with blue light from one carrier substrate and the other colors from the second carrier substrate. Tandem or stacked OLEDs also may be used to increase the overall brightness of individual devices, sub-panels, or the panel as a whole.

In scenarios where higher brightness may be desired, such as for outdoor signage, other arrangements may be used. For example, one sub-panel carrier substrate may include OLEDs that emit green light, and the other red and blue. In bright sunlight, for images to be readable, it may be more important to have high green luminance than full color gamut. More generally, embodiments disclosed herein may use two sets of OLEDs on the two sub-panels, one including a first color or set of colors and the other a second color or set of colors which in combination with the first provide the desired gamut for a full-color display.

In a one-sided display the image coming out of one side of the transparent display will be a superposition of the two images coming out of each sub-panel carrier substrate, for example one containing a yellow component and one a blue component as previously disclosed. To drive such an arrangement, the video signal provided to the display device may be processed in a frame buffer that separates the blue component from the GR, YGR or WGR components. The blue component then may be sent to one sub-panel carrier substrate for display while the non-blue components are sent to the other carrier substrate. The signals may be synchronized so the resultant image is correct. More generally, similar driving schemes can be used for other configurations, such as where one sub-panel includes blue devices and the other includes red and green, or for a green+red/blue as previously disclosed for outdoor signage applications.

For a two-sided display, it may be important that the same image is seen from either side of the display. To achieve this, each pixel in each sub-panel carrier substrate may have two sub-pixels for each color, where each of the two sub-pixels renders a different part of an image in each direction. In this configuration, each carrier substrate has double the number of sub-pixels, data lines, driver chips, and other associated electronics, in comparison to a one-sided display. That is, each pixel may include twice the conventional number of sub-pixels, one configured for top emission and one for bottom emission, and each pixel may include three regions—top emitting, bottom emitting, and non-emissive/transparent regions. Furthermore, not only is each image frame divided into its blue and non-blue components for each carrier substrate to render correctly (or other color separation as disclosed herein), but the video signal is also sent to the appropriate data lines and pixels on each carrier substrate corresponding to the direction from which the image will be viewed. Any suitable driving scheme and associated electronics may be used to do so, as are known in the art for conventional stacked and/or two-sided displays.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A transparent display device comprising:
a first organic light emitting diode (OLED) device comprising:
a first carrier substrate; and
a first organic emissive stack disposed over the first carrier substrate, the first organic emissive stack comprising a first emissive material of a first color;
a second OLED device disposed in a stack with the first OLED device; the second OLED device comprising:
a second carrier substrate different from the first substrate; and
a second organic emissive stack different from the first organic emissive stack and disposed over the second carrier substrate, the second organic emissive stack comprising a second emissive material of a second color different than the first color.

2. The device of claim 1, wherein neither the first color nor the second color comprises deep blue.

3. The device of claim 1, wherein the display device is at least 40% transparent.

4. The device of claim 3, wherein the display device has a luminance of at least 1000 nits.

5. The device of claim 1, wherein the first organic emissive stack is disposed between the first carrier substrate and the second carrier substrate.

6. The device of claim 5, wherein the second organic emissive stack is disposed between the first carrier substrate and the second carrier substrate.

7. The device of claim 5, wherein the second carrier substrate is disposed between the first organic emissive stack and the second organic emissive stack.

8. The device of claim 1, wherein the first carrier substrate and the second carrier substrate are disposed between the first organic emissive stack and the second organic emissive stack.

9. The device of claim 1, wherein the first OLED device is a top-emitting OLED.

10. The device of claim 9, wherein the second OLED device is a transparent OLED.

11. The device of claim 9, wherein the second OLED device is a bottom-emitting OLED.

12. The device of claim 1, wherein the first color comprises red, green, and/or yellow.

13. The device of claim 12, wherein the second color comprises blue.

14. The device of claim 12, wherein the second color comprises green and/or yellow.

15. The device of claim 14, wherein the first color comprises blue and/or red.

16. The device of claim 1, wherein the device emits light in only one direction.

17. The device of claim 1, wherein the device emits light in two directions.

18. The device of claim 1, wherein the device is capable of full-color emission.

19. The device of claim 1, wherein at least one of first and second OLEDs comprises a stacked device.

20. (canceled)

21. A transparent display panel comprising:
a first sub-panel comprising:
a first backplane layer; and
a first emissive layer comprising a plurality of OLED-based pixels disposed over the first backplane layer, wherein the first backplane layer provides control of the first emissive layer;
a second sub-panel comprising:
a second backplane layer; and
a second emissive layer comprising a plurality of OLED-based pixels disposed over the second backplane layer, wherein the second backplane layer provides control of the second emissive layer.

22-38. (canceled)
